(19) United States
(12) Patent Application Publication
(10) Pub. No.: US 2017/0316949 A1
(43) Pub. Date: Nov. 2, 2017

(54) METHOD OF ETCHING ATOMIC LAYER

(71) Applicants: RESEARCH & BUSINESS FOUNDATION SUNGKYUNKWAN UNIVERSITY, Suwon-si (KR); IUCF-HYU (Industry-University Cooperation Foundation Hanyang University), Seoul (KR)

(72) Inventors: Geunyoung YEOM, Seoul (KR); Kyong Nam KIM, Suwon-si (KR); Ki Seok KIM, Incheon (KR); Mu Kyeom MUN, Uiwang-si (KR); Jinwoo PARK, Goyang-si (KR); Deokhyeon YUN, Paju-si (KR); Jo-Won LEE, Seoul (KR)

(73) Assignees: RESEARCH & BUSINESS FOUNDATION SUNGKYUNKWAN UNIVERSITY, Suwon-si (KR); IUCF-HYU (Industry-University Cooperation Foundation Hanyang University), Seoul (KR)

(21) Appl. No.: 15/498,680

(22) Filed: Apr. 27, 2017

(30) Foreign Application Priority Data
Apr. 27, 2016 (KR) 10-2016-0051747

(51) Int. Cl. H01L 21/3065; H01J 37/32

(52) U.S. Cl. CPC H01L 21/3065; H01J 37/3244; H01J 37/32009; H01J 2237/334

(57) ABSTRACT

The present disclosure relates to a method of etching an atomic layer, that is capable of simultaneously removing an upper surface and a side surface of an etch subject material layer by heating with a light source of a lamp when removing the atomic layer, thereby easily reducing the planar size even in the case of patterns in the scale of several nanometers.

### CROSS-REFERENCE TO RELATED APPLICATIONS

This application claims priority from Korean Patent Application No. 10-2016-0051747, filed on Apr. 27, 2016, in the Korean Intellectual Property Office, the disclosure of which is incorporated herein by reference in its entirety.

### BACKGROUND

### Field

The present disclosure relates to a method of etching an atomic layer, and more particularly, to a method of etching an atomic layer that is capable of simultaneously removing a single atomic layer on an upper surface and on a side surface of an etch subject material layer, i.e., a layer of material to be etched, using a light source.

### Description of Related Art

In recent days, as needs for high density integration of semiconductor devices continue, in designing semiconductor integrated circuits, design rules have recently been further reduced to the extent of demanding that a critical dimension should be no more than 0.25 μm.

Currently, as etching equipment for realizing such nano grade semiconductor devices, etching equipment for ion reinforcement purposes, such as high density plasma etchers and reactive ion etchers and the like are mostly used.

FIG. 1 is a schematic view of a conventional atomic layer etcher. Referring to FIG. 1, the conventional atomic layer etcher is configured to include a reactive chamber 100 having an inlet 100a for introducing etching gas and an outlet 100b for discharging residual gas, a stage 110 provided inside the reactive chamber 100 to seat an etch subject substrate 120 (i.e., a substrate 120 to be etched), a shower ring 130 having a jet nozzle 131 for jetting the etching gas towards the substrate, and a plasma generator 140 for generating plasma so that a single atomic layer of an etch subject material formed on the etch subject substrate 120 may be removed.

An etching method that uses the aforementioned conventional atomic layer etcher works as follows. FIG. 2 is a schematic view of an adsorbing process of the etching gas, and FIG. 3 is a schematic view of a desorbing process of the etching gas.

First of all, referring to FIG. 2, the etch subject substrate 120 is loaded on top of the stage 110 inside the reactive chamber 100 and is seated, and then the etching gas is injected into the reactive chamber 100 through the inlet 100a.

Here, on the etch subject substrate 120, an etch subject material layer 121 (i.e., a layer 121 of material to be etched) is formed, and for selective etching, certain portions are shielded by a mask 120a.

Here, a gas that can react and combine with the etch subject material layer 121 formed on the etch subject substrate 120 is selected as the etching gas.

The etching gas is jetted from a certain supply unit towards the etch subject substrate 120 through the shower ring 130, and etching gas particles (a) are chemically combined with atoms 122 located on an uppermost layer of the etch subject material layer 121, that are exposed to the surface as they are not shielded by the mask 120a, and thus the gas particles are adsorbed to the atoms 122.

After the etching gas particles (a) are adsorbed to the surface of the etch subject material 121 as aforementioned, when a high energy plasma of several hundreds of eV is generated through the plasma generator 140 as illustrated in FIG. 3, at the portion of the etch subject material layer that is not shielded by the mask 120a and is thus exposed, the single atoms 122 located on the uppermost layer of the etch subject material layer 121 where the etching gas particles (a) are adsorbed, that is, the outermost surface, are removed from the etch subject material layer 121. By this method, the single atomic layer 121a of the etch subject material layer 122 is etched.

Here, since the adsorption rate of etching gas may generally improve when the adsorption is performed in a state where the temperature of the substrate is low, methods of exposing the substrate to etching gas while keeping the temperature of the substrate at room temperature have been used, but such methods have a problem that the time period of exposing the substrate to the etching gas becomes too long, thereby elongating the processing time.

Further, another problem was that where the etching gas jetted from the shower ring arrives at the etch subject material layer differs across the etch subject material layer, leaving some parts not adsorbed with the etching gas particles.

Further, another problem was that since there are massive amounts of ions in the reactive chamber to perform the etching process, and these ions collide with the semiconductor substrate or with a certain material layer on the semiconductor substrate at the energy of several hundreds of eV, physical and electrical damages on the semiconductor substrate or the certain material layer may occur.

Therefore, the physical and electrical damage caused by these ions deteriorate the reliability of the nanometer grade semiconductor devices, and further, becomes the cause of reducing productivity, and thus there is a need to develop a new concept of semiconductor etching equipment and etching method that can be applied in respond to the high density integration trend of semiconductor devices and reduction of design rules accompanying this high density integration trend.

### SUMMARY

Therefore, a purpose of the present disclosure is to solve the aforementioned problems of prior art, that is, to provide a method of etching an atomic layer, capable of removing a single atomic layer of an etch subject material layer by heating with a light source, so that an upper surface and a side surface of the etch subject material layer can be simultaneously removed.

Further, another purpose of the present disclosure is to provide a method of etching an atomic layer, capable of simultaneously removing the upper surface and the side surface of the etch subject material layer, so that the planar size of even the etch subject material layers in the scale of several nanometers can be easily reduced.

Further, another purpose of the present disclosure is to provide a method of etching an atomic layer, capable of cooling the etch subject material layer when adsorbing the etching gas to the etch subject material layer, so that the adsorption rate of the etching gas can be improved.

The aforementioned purposes may be achieved by a method of etching an atomic layer according to an embodiment of the present disclosure, the method including adsorbing step of adsorbing an etching gas to a surface of an etch subject material layer of an etch subject substrate by injecting the etching gas into a reactive chamber; and removing step of removing from the etch subject material layer a single atomic layer existing on a surface of the etch subject material layer where the etching gas is adsorbed, by heating the etch subject material layer using a light source.

Here, at the adsorbing step, the etching gas may be adsorbed to an upper surface and a side surface of the etch subject material layer, so that when the single atomic layer is removed at the removing step, the single atomic layer on the upper surface and the single atomic layer on the side surface of the etch subject material layer are simultaneously removed.

Further, at the adsorbing step, the etching gas may preferably be adsorbed to the surface of the etch subject material layer by being combined with radicals or ions of a plasma.

Further, the light source may preferably be a halogen lamp or an ultraviolet ray lamp.

Further, in case that the lamp is the halogen lamp, the heating condition at the removing step may be: a wavelength of 400 nm to 800 nm, and a temperature of 100° C. to 500° C.

Further, in case that the lamp is the ultraviolet ray lamp, the heating condition at the removing step may be: a wavelength of 10 nm to 400 nm, and an energy level of 3.1 eV to 124 eV.

According to the present disclosure, there is provided a method of etching an atomic layer, capable of removing a single atomic layer of an etch subject material layer by heating with a heat source, so that an upper surface and a side surface of the etch subject material layer can be simultaneously removed.

Further, there is provided a method of etching an atomic layer, capable of simultaneously removing the upper surface and the side surface of the etch subject material layer, so that the planar size of even the etch subject material layers in the scale of several nanometers can be easily reduced.

Further, there is provided a method of etching an atomic layer, capable of cooling the etch subject material layer when adsorbing the etching gas to the etch subject material layer, so that the adsorption rate of the etching gas can be improved.

### BRIEF DESCRIPTION OF THE DRAWINGS

FIG. 1 is a schematic view illustrating a conventional atomic layer etcher;

FIGS. 2 and 3 are views illustrating an etching process using the conventional atomic layer etcher;

FIG. 4 is a view illustrating a manufacturing process during adsorption in a method of etching an atomic layer according to an embodiment of the present disclosure;

FIG. 5 is a view illustrating a manufacturing process during removal in a method of etching an atomic layer according to the embodiment of the present disclosure;

FIG. 6 is a view illustrating a manufacturing process during adsorption in a method of etching an atomic layer according to another embodiment of the present disclosure; and

FIG. 7 is a view illustrating a manufacturing process during removal in a method of etching an atomic layer according to another embodiment of the present disclosure.

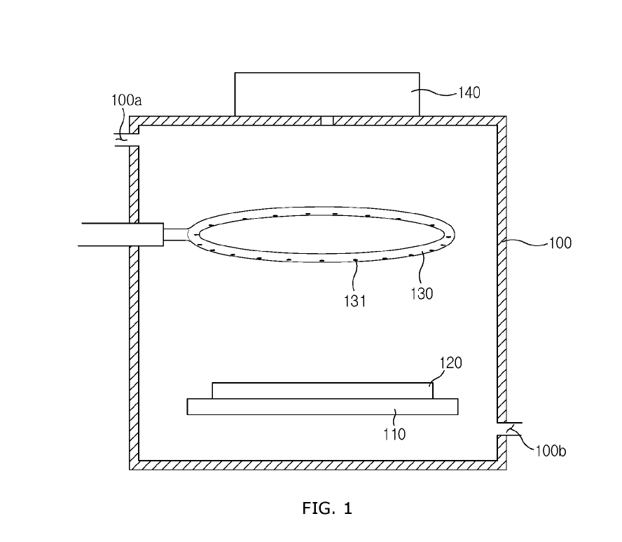

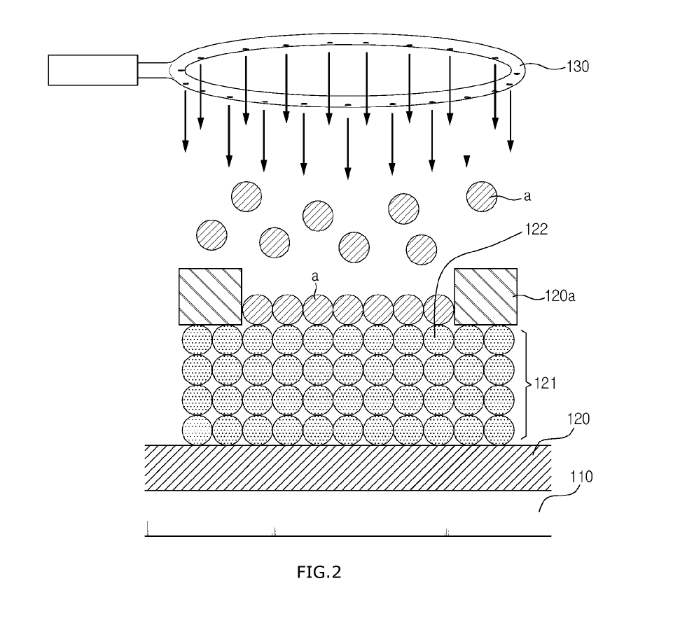

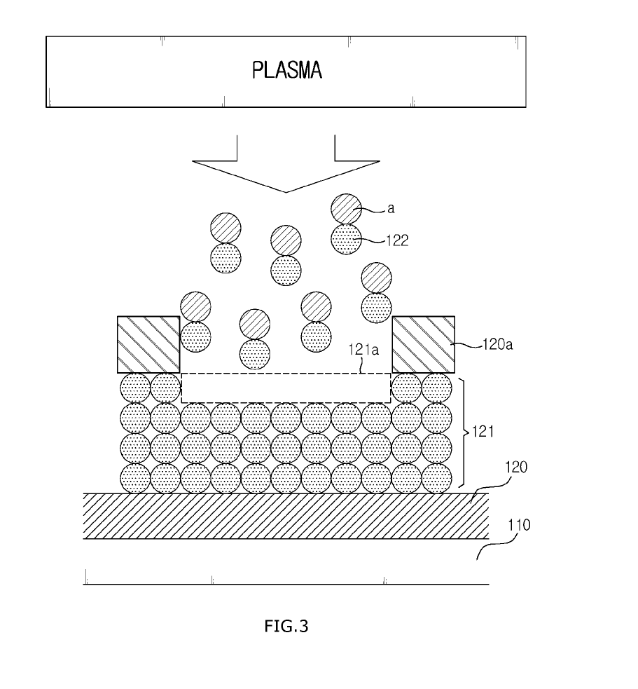

### DETAILED DESCRIPTION

Prior to describing the present disclosure, it is to be noted that like configurations throughout the various embodiments will be described representatively in one embodiment using like reference numerals, and in the rest of the embodiments, only the configurations that are different from those in the first embodiment will be described.

Hereinafter, a method of etching an atomic layer according to an embodiment of the present disclosure will be described in detail with reference to the drawings attached.

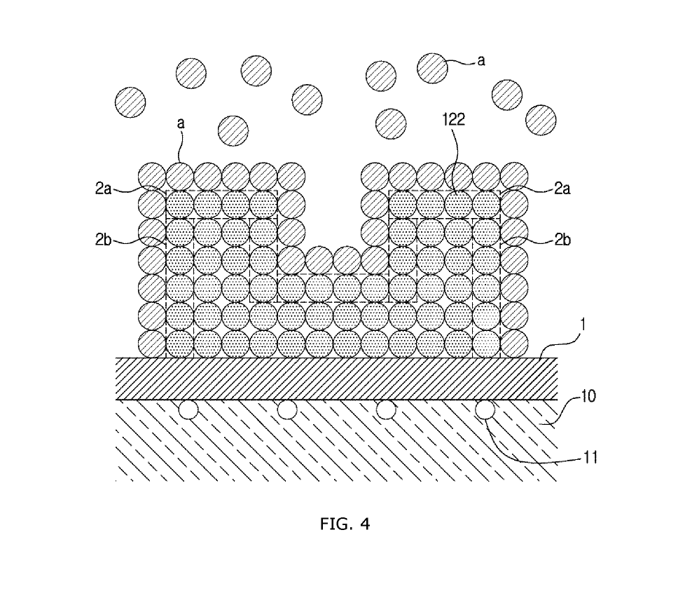

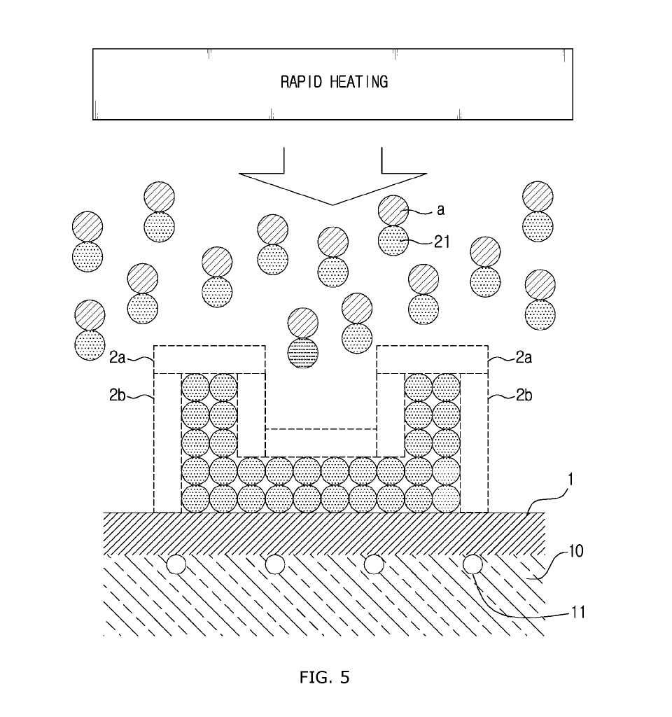

FIG. 4 is a view illustrating a manufacturing process during adsorption in a method of etching an atomic layer according to an embodiment of the present disclosure, and FIG. 5 is a view illustrating a manufacturing process during removal in the method of etching an atomic layer according to the embodiment of the present disclosure.

With reference to FIG. 4, a reactive chamber (not illustrated) has therein a stage 10 on which an etch subject substrate 1 may be seated.

The reactive chamber is provided with a plasma generator and the like for generating plasma, and a remote system or a general ICP system may be applied.

The etch subject substrate 1 on which an etch subject material layer 2 is formed is transferred into the reactive chamber that is prepared as aforementioned, and seated on an upper portion of the stage 10. On an upper surface of the etch subject substrate 1, the etch subject material layer 2 is formed and provided in a certain pattern shape.

In this state, when the etching gas (a) is injected, the etching gas (a) is adsorbed to a single atomic layer (2a) which is present at an upper surface of the etch subject material layer 2, and to a single atomic layer (2b) which is present at a side surface (trench) of the etch subject material layer 2, the single atomic layer (2a) and the single atomic layer (2b) being the exposed portions.

Here, the etching gas (a) may be adsorbed to the surface of the etch subject material layer 2 as it combines with radicals or ions of a plasma, or may be adsorbed on the surface of the etch subject material layer 2 in the form of molecules without additional energy source.

For example, assuming that radicals are formed through the plasma and an etch subject substrate is provided that is made of a silicone material, as the radicals of the plasma are in a very unstable state, they will try to react with something, and thus, the radicals will take away outermost electrons of silicone atoms to form a compound on the surface of the etch subject substrate, whereby adsorption will be performed. In this principle, the etching gas is adsorbed to the surface of the etch subject material layer.

In such an adsorbed state, as illustrated in FIG. 5, the etch subject substrate is heated using a light source such as a halogen lamp or an ultraviolet ray lamp located on the upper portion of the etch subject substrate 1.

Here, in the case where the light source is the halogen lamp, it is preferable that the wavelength is 400 nm to 800 nm and the temperature is 100° C. to 500° C., and in the case where the light source is the ultraviolet ray lamp, the wavelength is 10 nm to 400 nm and the energy level is 3.1 eV to 124 eV.

When the aforementioned energy is applied to the etch subject substrate, by the linearity and spreadability (conductivity) of heat, the single atomic layers 2a, 2b on the upper surface and the side surface (trench) of the etch subject material layer 2 may be etched.

By doing this, in the case of etching using plasma which is a conventional method, anisotropic etching is allowed such that the plasma beam may be injected towards the etch subject substrate only in a vertical direction due to the linearity of the plasma beam. Unlike the conventional method, the present disclosure allows isotropic etching where etching may be proceeded in any direction.

By doing this, it is possible to reduce the size of the etch subject material layer 2 not only in the height direction, but also in the width or longitudinal direction.

Utilizing this, it becomes easier to form patterns having the size of several nanometers, thereby making it easier to manufacture nano-grade devices.

Meanwhile, on the stage 10, a cooling means 11 for cooling the etch subject substrate 1 may be installed. The cooling means 11 may be controlled to cool the etch subject substrate 1 when adsorbing the etching gas (a).

This may improve the adsorption rate of the etch subject material layer 2, and shorten the period of time during which the etch subject substrate 1 is exposed to the etching gas (a).

Between each of the aforementioned adsorbing process and the removing process, a purge process using purge gas being supplied into the reactive chamber may be performed.

Accordingly, in the case of performing the four steps: \hat{1} adsorbing process, \hat{2} purge process, \hat{3} removing process and \hat{4} purge process, i.e. the basic configuration for removing an atomic layer, as one cycle, one atomic layer may be removed every time one cycle is completed.

Next, another embodiment of the present disclosure will be explained. Unlike the aforementioned embodiment, this another embodiment of the present disclosure is configured such that a mask exposing only the portion to be etched is coupled to the upper portion of the etch subject material 2 formed on the etch subject substrate.

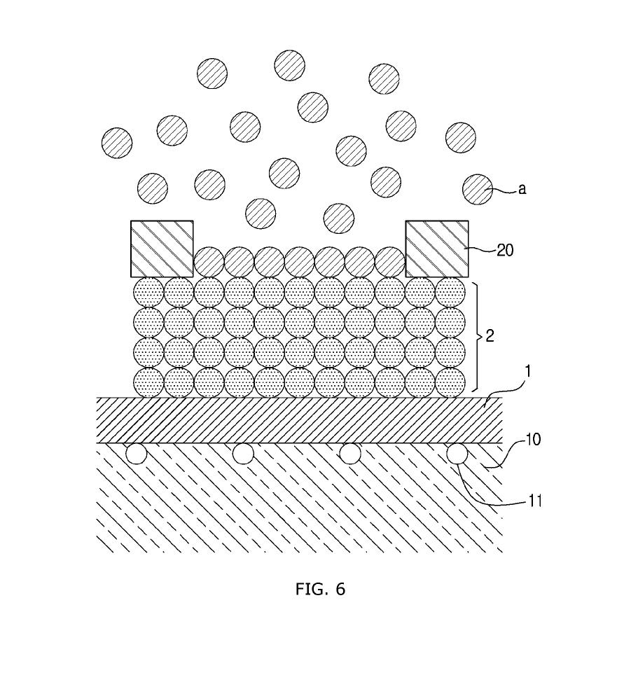

That is, as illustrated in FIG. 6, the etch subject substrate 1 is seated on the upper portion of the stage with the mask 20 being coupled, and then the etching gas (a) is injected into the reactive chamber.

The etching gas (a) being injected reacts with the atoms 21 of the etch subject material located on the upper surface of the etch subject material layer 2, that is, the exposed portion of the surface of the etch subject material layer 2 by not being shielded by the mask 20, and thus the etching gas (a) is adsorbed.

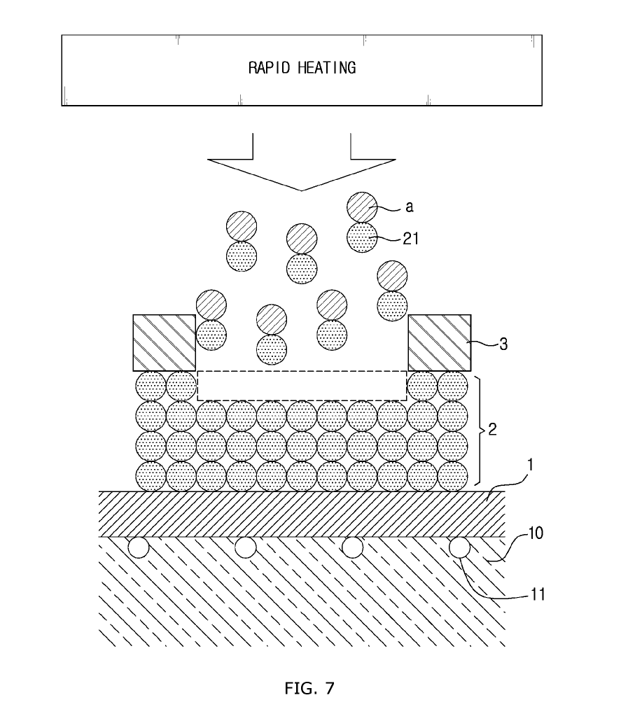

With the etching gas (a) adsorbed to the exposed portion on the upper surface of the etch subject material layer 2, as illustrated in FIG. 7, the etch subject material layer 2 may be heated using the light source (not illustrated) such as a lamp and the like, so as to remove the atoms 21 of the etch subject material combined with the etching gas (a), thereby removing the single atomic layer of the etch subject material layer 2.

The right of the scope of the present disclosure is not limited to the aforementioned embodiments but may be realized in various types of embodiments within the claims attached hereto. It will be apparent to one of ordinary skill in the art that various changes in form and details may be made in these examples without departing from the spirit and scope of the claims and their equivalents.

### REFERENCE NUMERALS

a: ETCHING GAS
1: ETCH SUBJECT SUBSTRATE
2: ETCH SUBJECT MATERIAL LAYER
2a: SINGLE ATOMIC LAYER OF UPPER SURFACE OF ETCH SUBJECT MATERIAL LAYER
2b: SINGLE ATOMIC LAYER OF SIDE SURFACE OF ETCH SUBJECT MATERIAL LAYER
10: STAGE
11: COOLING MEANS
20: MASK
21: ATOMS OF ETCH SUBJECT MATERIAL

What is claimed is:

1. A method of etching an atomic layer atomic layer comprising:
adsorbing step of adsorbing an etching gas to a surface of an etch subject material layer of an etch subject substrate by injecting the etching gas into a reactive chamber; and
removing step of removing from the etch subject material layer a single atomic layer existing on a surface of the etch subject material layer where the etching gas is adsorbed, by heating the etch subject material layer using a light source.

2. The method of claim 1,
wherein at the adsorbing step, the etching gas is adsorbed to an upper surface and a side surface of the etch subject material layer such that when the single atomic layer is removed at the removing step, the single atomic layer on the upper surface and the single layer on the side surface of the etch subject material layer are simultaneously removed.

3. The method of claim 1,
wherein at the adsorbing step, the etching gas is adsorbed to the surface of the etch subject material layer by being combined with radicals or ions of a plasma.

4. The method of claim 1,
wherein the light source is a halogen lamp or an ultraviolet ray lamp.

5. The method of claim 4,
Wherein in case that the lamp is the halogen lamp, a wavelength is 400 nm to 800 nm, and a temperature is 100° C. to 500° C.

6. The method of claim 4,
Wherein in case that the lamp is the ultraviolet ray lamp, a wavelength is 10 nm to 400 nm, and an energy level is 3.1 eV to 124 eV.
